(19) United States
(12) Patent Application Publication
(10) Pub. No.: US 2007/0205819 A1
(43) Pub. Date: Sep. 6, 2007

(54) Delay circuit with constant delay time regardless of process condition or voltage variation and pulse generator using the same

(75) Inventor: San-Ha Park, Ichon-shi (KR)

Correspondence Address: LOWE HAUPTMAN BERNER, LLP, 1700 DIAGONAL ROAD, SUITE 300, ALEXANDRIA, VA, 22314, US

(73) Assignee: Hynix Semiconductor, Inc.

(21) Appl. No.: 11/797,263

(22) Filed: May 2, 2007

Related U.S. Application Data
(62) Division of application No. 10/874,741, filed on Jun. 24, 2004.

(30) Foreign Application Priority Data
Oct. 31, 2003 (KR) 2003-76839

(51) Int. Cl. H03H 11/26

(52) U.S. Cl. 327/288

(57) ABSTRACT

A delaying circuit is capable of constantly maintaining its delay regardless of process condition or voltage variation and a pulse generating circuit uses the delaying circuit. The delay circuit for delaying a signal that is inputted to an input stage by a predetermined time to output to an output stage, comprises a pull-up unit for pulling up the output stage in response to the signal that is inputted to the input stage, the pull-up unit including a first resistor device and a first MOS transistor that is maintained in turn-on state and is coupled to the first resistor device in parallel to delay the signal that is inputted to the input stage by the predetermined time; and a pull-down unit for pulling down the output stage in response to the signal that is inputted to the input stage.

### CROSS REFERENCE TO RELATED APPLICATION

This application is a divisional of U.S. Ser. No. 10/874,741, filed on Jun. 24, 2004. This application, in its entirety, is incorporated herein by reference.

### FIELD OF THE INVENTION

The present invention relates to a semiconductor integrated circuit; and, more particularly, to a pulse generating circuit for outputting a pulse signal having a constant pulse width regardless of process condition or voltage variation.

### BACKGROUND OF THE INVENTION

FIG. 1 provides a circuit diagram of a pulse generating circuit in prior art.

Referring to FIG. 1, the conventional pulse generating circuit comprises a first pulse generating unit 20 for generating a first pulse B by using an input signal In, a delaying unit 10 for delaying the input signal In by a predetermined time, a second pulse generating unit 30 for generating a second pulse D by using the output of the delaying unit 10, and a signal combining unit 40 for outputting a pulse signal Pulse Out by using the outputs of the first and the second pulse generating unit 20, 30.

FIGS. 2a to 2c show circuit diagrams of embodiments of the delaying unit in FIG. 1.

In FIG. 2a, the delaying unit 10 in FIG. 1 is implemented by using a number of inverters I9-I4 serially coupled sequentially. In FIG. 2b, the delaying unit 10 is implemented by using a number of resistors R1, R2, inverters I15, I18 and capacitors C1-C4. In FIG. 2c, the delaying unit 10 is implemented by using inverters and resistors R3, R4 that are arranged between drains and outputs of a PMOS transistor MP1 and a NMOS transistor MN2 included in the inverters, respectively.

FIG. 3 describes a waveform diagram for operation of a pulse generating circuit in FIG. 1. It will be described for the operation of the pulse generating in prior art with reference to FIG. 1 to 3.

When an input signal In is inputted, which maintains in a low level and have a high level for a while, the first pulse generating unit 20 generates the first pulse signal B by using rising transition of the input signal In. Inverters I1-I3 of the first pulse generating unit 20 invert the input signal In. A NAND gate ND1 of the pulse generating unit 20 outputs the first pulse signal B that has the low level for the period during which both of the input signal In and the output of the inverter I3 are in the high level.

On the other hand, the delaying unit 20 delays the rising transition of the input signal in by the predetermined time. The second pulse generating unit 30 generates the second pulse signal D by using the rising transition of the output signal In_D of the delaying unit 20. The second pulse generating unit 30 includes inverters I4-I6 for inverting the output signal In_D of the delaying unit 10, and a NANS gate ND2 for outputting the second pulse signal D that has the low level for the period during which both of the output signal In_D of the delaying unit 10 and the output of the inverter I6 are in the high level.

In turn, the signal combining unit 40 outputs the pulse signal Pulse Out that has the high level between transition of the first pulse signal B to the low level and transition of the second pulse signal D to the low level.

Here, the pulse width of the outputted pulse signal Pulse Out is determined depending on the time that is delayed by the delaying unit 10. Accordingly, it is very critical to constantly maintain the delay time for the input signal in the delaying unit 10 regardless of process condition or voltage variation.

As described above, the delaying unit 10 in prior art is implemented by the serially coupled inverters (see FIG. 2a) or the RC delay (see FIG. 2b). When the delaying unit 10 uses the inverters, the delay time of the delaying unit 10 shows significant variation due to process condition or driving voltage variation because of the characteristic of the inverters. For example, if the driving voltage of the inverter is increased or the MOS transistor in the inverter happens to have a shorter channel in the process, the delay time of the delaying unit is significantly decreased.

Further, when the delaying unit 10 uses the RC delay, if the driving voltage level is increased, the delay is increased to make it difficult to maintain the pulse width constantly, which can lead any error. For example, if the driving voltage is high, the width of the pulse signal is increased. If the pulse signal is used as a reset signal of a next circuit, the next circuit can operate erroneously due to improper reset.

In order to solve such a problem, the delaying unit 10 using the RC delay replaces the resistor part with active resistors (turn-on resistors of the MOS transistors, see FIG. 2c). However, in the active resistor, it is difficult to adjust the delay because its contact resistance value is very sensitive to the process condition.

From the above, it can be noticed that waveform variation (shown as dotted in FIG. 3) of the first pulse signal B, the second pulse signal D and the output signal of the delaying unit 10 is significant due to variation of the delay of the delaying unit 10, which can be troublesome. Further, it can be seen that the width of the outputted pulse signal Pulse Out is varied significantly, accordingly (see the X and Y period).

FIG. 4 exemplifies a chart for variation of a pulse signal that is outputted while a voltage level of a power voltage varies when the delaying units in FIGS. 2a and 2c are applied in the pulse generating circuit in FIG. 1.

Referring to FIG. 4, when the delaying unit 10 is implemented by using the inverters in FIG. 2a and the power voltage is changed from 2.2V to 4.0V, the width of the outputted pulse signal Pulse Out goes dramatically from 2.28 n to 1.54 n.

Further, when the delaying unit 10 is implemented as shown in FIG. 2c, the width of the outputted pulse signal Pulse Out is 3.56 n in case of 2.2V, the width of the outputted pulse signal Pulse Out is 4.16 n in case of 3.5V, and the pulse signal Pulse Out is not generated in case of 4.0V. Such a result comes out because the delay of the delaying unit 10 is increased so much so as to have a longer delay than the high period of the input signal In.

### SUMMARY OF THE INVENTION

It is, therefore, a primary object of the present invention to provide a delaying circuit capable of constantly maintaining its delay regardless of process condition or voltage variation and a pulse generating circuit using the same.

In accordance with the present invention, there is provided a delay circuit for delaying a signal that is inputted to an input stage by a predetermined time to output to an output stage, which comprises a pull-up unit for pulling up the output stage in response to the signal that is inputted to the input stage, the pull-up unit including a first resistor device and a first MOS transistor that is maintained in turn-on state and is coupled to the first resistor device in parallel to delay the signal that is inputted to the input stage by the predetermined time; and a pull-down unit for pulling down the output stage in response to the signal that is inputted to the input stage.

Further, in accordance with the present invention, there is provided a delay circuit for delaying a signal that is inputted to an input stage by a predetermined time to output to an output stage, which comprises a pull-up unit for pulling up the output stage in response to the signal that is inputted to the input stage; and a pull-down unit for pulling down the output stage in response to the signal that is inputted to the input stage, the pull-down unit including a first resistor device and a first MOS transistor that is maintained in turn-on state and is coupled to the first resistor device in parallel to delay the signal that is inputted to the input stage by the predetermined time.

Further, in accordance with the present invention, there is provided a delay circuit for delaying a signal that is inputted to an input stage by a predetermined time to output to an output stage, which comprises a pull-up unit for pulling up the output stage in response to the signal that is inputted the input stage; a first delay device arranged between the pull-up unit and the output stage and including a first resistor device and a first MOS transistor that is maintained in turn-on state and is coupled to the first resistor device in parallel; and a pull-down unit for pulling down the output stage in response to the signal that is inputted to the input stage; and a second delay device arranged between the pull-down unit and the output stage and including a second resistor device and a second MOS transistor that is maintained in the turn-on state and is coupled to the second resistor device in parallel.

Further, in accordance with the present invention, there is provided a delay circuit for delaying a signal that is inputted to an input stage by a predetermined time to output to an output stage, which comprises a first MOS transistor having one end coupled to a power voltage for transferring the power voltage to the signal transfer node in response to the signal that is inputted to the input stage; a first delay device coupled between the other end of the first MOS transistor and the signal transfer node and having a first resistor device and a second MOS transistor that is maintained in turn-on state and is coupled to the first resistor device in parallel; a third MOS transistor having one end coupled to a ground voltage for transferring the ground voltage to the signal transfer node in response to the signal that is inputted to the input stage; a fourth MOS transistor having one end coupled to the power voltage for transferring the power voltage to the output stage in response to the signal that is inputted to the signal transfer node; a fifth MOS transistor having one end coupled to the ground voltage for transferring the ground voltage to the output stage in response to the signal that is inputted to the signal transfer node; and a second delay device coupled between the fifth MOS transistor and the output stage and having a second resistor device and a sixth MOS transistor that is maintained in the turn-on state and is coupled to the second resistor device in parallel.

Further, in accordance with the present invention, there is provided a pulse generating circuit comprising a first pulse generating unit for generating a first pulse signal by using transition of an input signal; a delaying unit for delaying the input signal by a predetermined time; a second pulse generating unit for generating a second pulse signal by using the transition of the output signal of the delaying unit; and a signal combining unit for receiving the first pulse signal and the second pulse signal to generate an output pulse signal, wherein the delaying unit includes a pull-up unit for pulling up an output stage in response to a signal that is inputted to an input stage; a first delaying device arranged between the pull-up unit and the output stage and having a first resistor device and a first MOS transistor that is maintained in turn-on state and is coupled to the first resistor device in parallel; a pull-down unit for pulling down the output stage in response to the signal that is inputted to the input stage; and a second MOS transistor arranged between the pull-down unit and the output stage and having a second resistor device and a second MOS transistor that is maintained in the turn-on state and is coupled to the second resistor in parallel.

Further, in accordance with the present invention, there is provided a pulse generating circuit comprising a first pulse generating unit for generating a first pulse signal by using transition of an input signal; a delaying unit for delaying the input signal by a predetermined time; a second pulse generating unit for generating a second pulse signal by using the transition of the output signal from the delaying means; and a signal combining unit for receiving the first pulse signal and the second pulse signal to generate an output pulse signal, wherein the delaying unit includes a first MOS transistor having one end coupled to a power voltage for transferring the power voltage to the signal transfer node in response to the signal that is inputted to the input stage; a first delay device coupled between the other end of the first MOS transistor and the signal transfer node and having a first resistor device and a second MOS transistor that is maintained in turn-on state and is coupled to the first resistor device in parallel; a third MOS transistor having one end coupled to a ground voltage for transferring the ground voltage to the signal transfer node in response to the signal that is inputted to the input stage; a fourth MOS transistor having one end coupled to the power voltage for transferring the power voltage to the output stage in response to the signal that is inputted to the signal transfer node; a fifth MOS transistor having one end coupled to the ground voltage for transferring the ground voltage to the output stage in response to the signal that is inputted to the signal transfer node; and a second delay device coupled between the fifth MOS transistor and the output stage and having a second resistor device and a sixth MOS transistor that is maintained in the turn-on state and is coupled to the second resistor device in parallel.

### BRIEF DESCRIPTION OF THE DRAWINGS

The above and other objects and features of the present invention will become apparent from the following description of preferred embodiments given in conjunction with the accompanying drawings, in which:

FIG. 1 provides a circuit diagram of a pulse generating circuit in prior art;

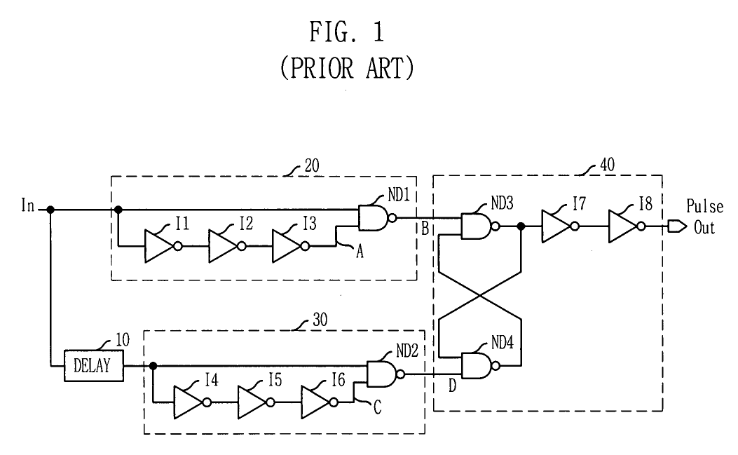

FIGS. 2a to 2c show circuit diagrams of embodiments of a delaying unit in FIG. 1;

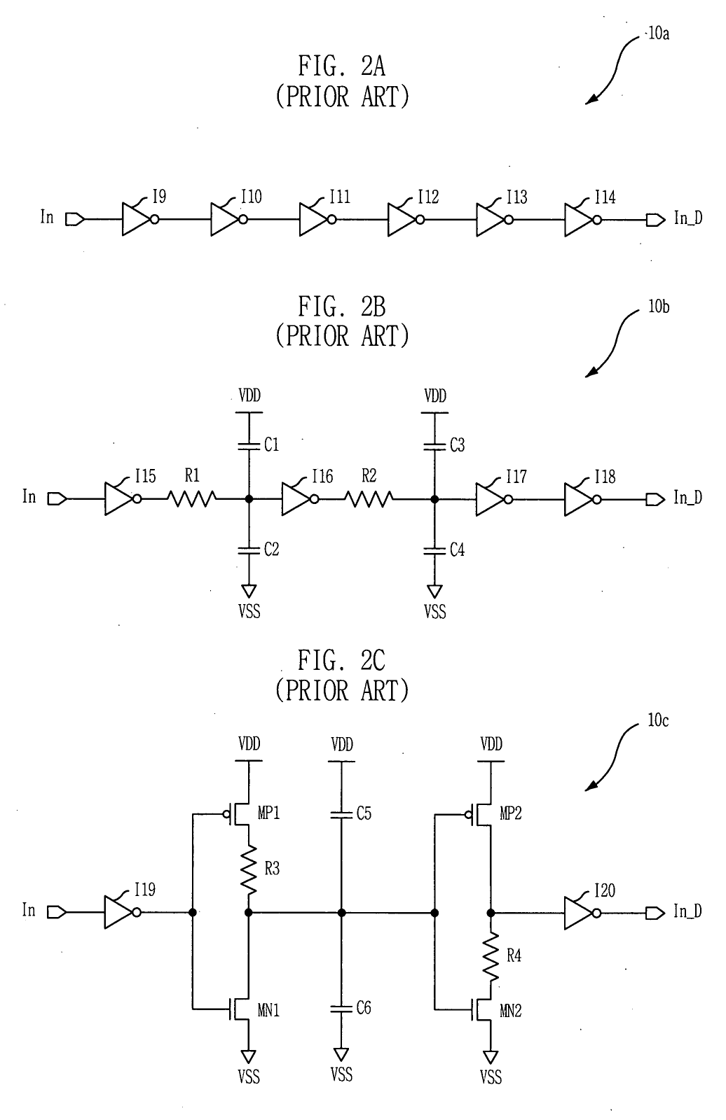

FIG. 3 describes a waveform diagram for operation of a pulse generating circuit in FIG. 1;

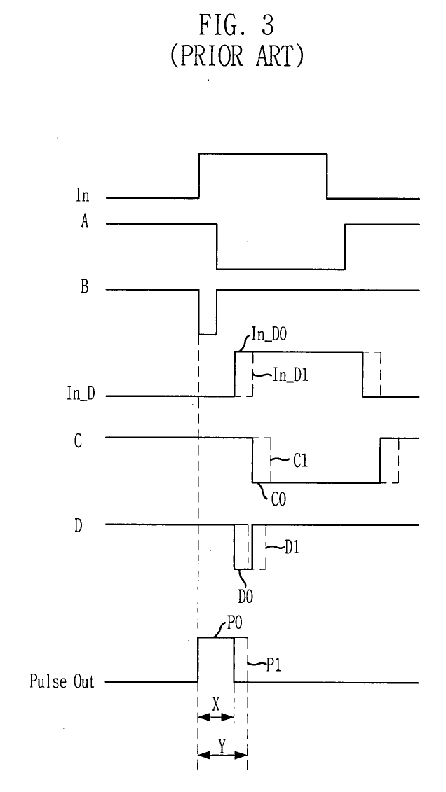

FIG. 4 exemplifies a chart for variation of a pulse signal that is outputted while a voltage level of a power voltage varies when the delaying units in FIGS. 2a and 2c are applied in the pulse generating circuit in FIG. 1;

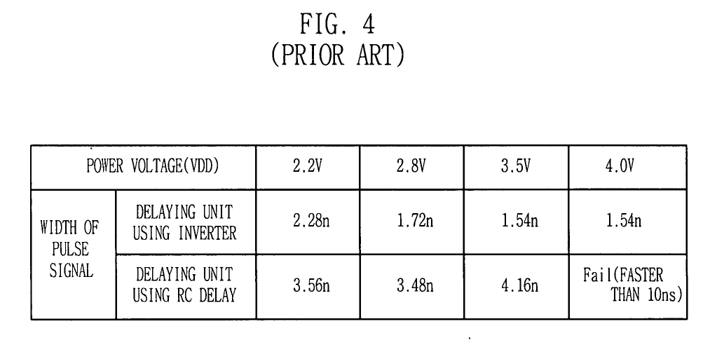

FIG. 5 represents a circuit diagram of a delaying circuit in accordance with one embodiment of the present invention;

FIG. 6 illustrates a circuit diagram of a delaying circuit in accordance with another embodiment of the present invention;

FIG. 7 shows a circuit diagram of a pulse generating circuit using the delaying circuit in FIG. 6;

FIG. 8 provides a waveform diagram for operation of the pulse generating circuit in FIG. 6; and

FIG. 9 offers a chart for comparing pulse width of the output of the pulse generating circuit in FIG. 5 to pulse width of the output of the pulse generating circuit in prior art when a power voltage of a power voltage varies.

### DETAILED DESCRIPTION OF THE PREFERRED EMBODIMENTS

Hereinafter, with reference to the accompanying drawings, a preferred embodiment of the present invention will be explained in detail.

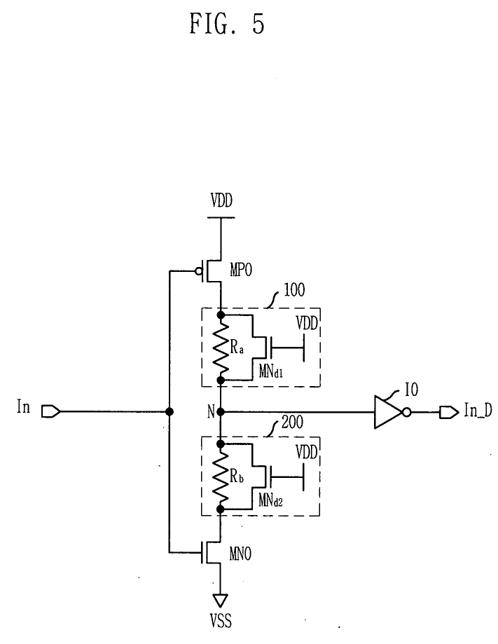

FIG. 5 represents a circuit diagram of a delaying circuit in accordance with one embodiment of the present invention.

Referring to FIG. 5, the delaying circuit according to the present invention includes a pull-up transistor MP0 for pulling up an output node N in response to an input signal In that is inputted the input stage, a first delay device 100 arranged between the pull-up transistor MP0 and the output node N and including a first resistor device Ra and a MOS transistor MNd1 coupled to the first resistor device Ra in parallel and maintained in turn-on state, a pull-down transistor MN0 for pulling down the output node N in response to the signal In that is inputted the input stage, and a second delay device 200 arranged between the pull-down transistor MN0 and the output node N and including a second resistor device Rd2 and a second MOS transistor MNd2 coupled to the second resistor device Rd2 in parallel and maintained in turn-on state.

Referring to FIG. 5, in the operation of the delaying circuit according to the embodiment of the present invention, when the input signal In is inputted in a low level, the pull-up transistor MP0 is turned on to make the node N rise to a power voltage level. At this time, the input signal is delayed at the first delay device 100 by a predetermined time. The high level signal that is inputted to the node N is inverted by an inverter to be outputted in the low level.

Here, the first delay device 100 includes a passive resistor Ra and an active resistor (the turn-on resistor of the transistor MNd1) coupled to each other in parallel so that it can maintain the delay time constantly even when the process condition or the voltage level is changed.

If the power voltage level is increased, the resistance of the active resistor gets to decrease but the resistance of the passive resistor gets to decrease complementarily so that the delay of the delaying device 100 can be maintained constantly.

Further, if process condition is changed, e.g., when the length of the channel of the MOS transistor is shortened, the resistance of the turn-on resistor gets to decrease but the resistance of the passive resistor gets to increase so that the entire resistance of the delay device 100 can be maintained constantly.

When the input signal In is inputted in the high level, the pull-down MOS transistor MN0 is turned on to make the node N in the low level. At that time, the input signal is delayed at the second delay device 200 by a predetermined time to make the node N in the low level. The second delay device 200 includes the passive resistor Rb and an active resistor (the turn-on resistor of the MOS transistor MNd2) coupled to each other in parallel so that the delay time can be maintained constantly even if the power voltage level or the process condition is changed.

Here, through the delay circuit is described as including the delaying devices 100, 200 arranged between the pull-up transistor MP0 and the node N and between the pull-down transistor MN0 and the node N, respectively, it can be understood that only one of the delay device 100 on the side of the pull-up transistor MP0 and the delay device 200 on the side of the pull-down transistor MN0 can be included in the delaying circuit.

Further, through the delay device 100 is described as arranged between the pull-up transistor MP0 for transferring the power voltage VDD and the node N, the delay device 100 can be arranged between the power voltage VDD and the pull-up transistor MP0.

Further, through the delay device 200 is described as arranged between the pull-down transistor MN0 and the node N, the delay device 200 can be arranged between the ground voltage VSS and the pull-down transistor MN0.

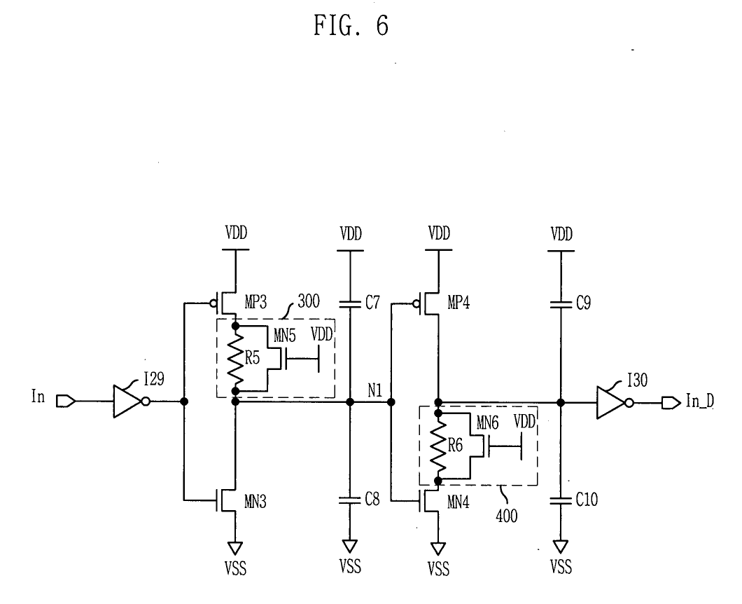

FIG. 6 illustrates a circuit diagram of a delaying circuit in accordance with a second embodiment of the present invention.

The delaying circuit of the second embodiment includes a MOS transistor MP3 having one end coupled to the power voltage VDD for transferring the power voltage VDD to a signal transfer node N1 in response to the input signal In, a first delay device 300 coupled between the other end of the MOS transistor MP3 and the signal transfer node N1 and having a first resistor device R5 and a MOS transistor MN5 coupled to the first resistor R5 device in parallel and maintained in the turn-on state, a MOS transistor MN3 having one end coupled to the ground voltage VSS for transferring the ground voltage VSS to the signal transfer node N1 in response to the input signal In, a MOS transistor MP4 having one end coupled to the ground voltage VSS for transferring the power voltage VSS in response to the signal that is inputted to the signal transfer node N1, and a second delay device 400 coupled between the other end of the MOS transistor MN4 and the other end of the MOS transistor MP4 and having a second resistor device R6 and a MOS transistor MN6 coupled to the second resistor device R6 in parallel and maintained in the turn-on state.

Further, the delay circuit according to the second embodiment includes an inverter I29 for inverting the input signal to output the inverted input signal to the gates of the MOS transistors MN3, MP3, and an inverter I30 for inverting the signal from the other end of the MOS transistor MP4.

Further, the delay circuit according to the second embodiment includes a capacitor C7 coupled between the power voltage VDD and the signal transfer node N1, and a capacitor C8 coupled between the ground voltage VSS and the signal transfer node N1.

The delay circuit according to the second embodiment is formed to delay the rising transition of the input signal In by a predetermined time to output the delayed input signal In_D but not to delay the falling transition of the input signal In. Though it is not shown in FIG. 6, a delay circuit that is capable of only delaying the falling transition period of the input signal In. In that case, the delay devices 300, 400 are coupled to the other ends of the MOS transistors MN3, MP4.

The delay circuit of the second embodiment can maintain its delay constantly regardless of process condition or voltage variation because the active resistors MN5, MN6 and the passive resistors R5, R6 are coupled in parallel in the delay devices 300, 400 that are included on the delay.

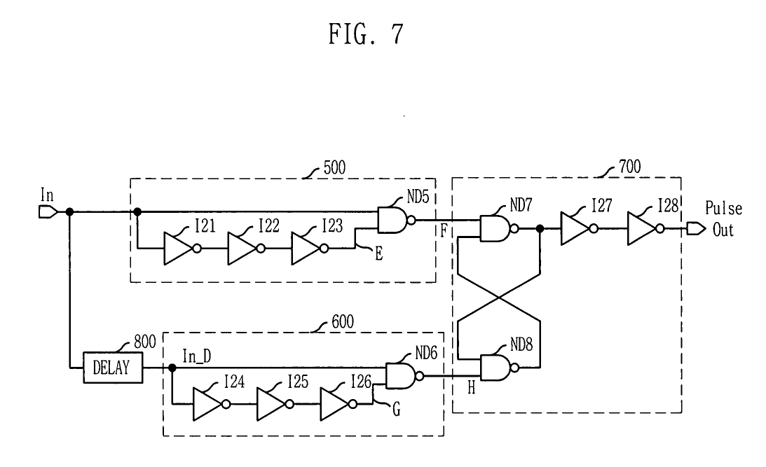

FIG. 7 shows a circuit diagram of a pulse generating circuit using the delaying circuit in FIG. 6.

Referring to FIG. 7, the pulse generating circuit includes a first pulse generating unit 500 for generating the first pulse signal F by using the transition of the input signal In, a delaying unit 800 for delaying the input signal In by a predetermined time, a second pulse generating unit 600 for generating a second pulse signal H by using the transition of the output signal from the delaying unit 10, and a signal combining unit 700 for generating an output pulse signal Pulse Out by using the first pulse signal F and the second pulse signal H. The delaying unit 800 uses the delay circuit shown in FIG. 5 or the delay circuit shown in FIG. 6.

The first pulse generating unit 500 includes inverters I21, I22, I23 for inverting the input signal In, and a NAND gate ND5 for receiving the input signal In and the output of the inverter I23.

The second pulse generating unit 600 includes inverters I24, I25, I26, for inverting the output of the delaying unit 800 and a NAND gate ND6 for receiving the output of the delaying unit 800 and the output of the inverter I26.

The signal combining unit 700 includes NAND gates ND7, ND8, the NAND gate ND7 receiving the output of the first pulse generating unit 500 and the output of the NAND gate ND8 and the NAND gate ND8 receiving the output of the second pulse generating unit 600 and the output of the NAND gate ND7, and a buffer I27, I28 for buffering the outputs of the NAND gates ND7, ND8.

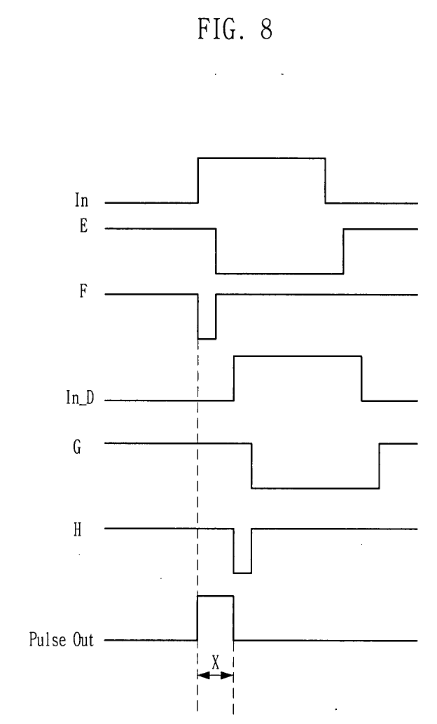

FIG. 8 provides a waveform diagram for operation of the pulse generating circuit in FIG. 6. It will be described for the operation of the pulse generating circuit with reference to FIGS. 7 and 8.

When the input signal In is inputted, which maintains the low level and has the high level for a while, the first pulse generating unit 500 generates the first pulse signal F by using the rising transition of the input signal In. On the other hand, the delaying unit 800 delays the rising transition period of the input signal by the predetermined time. The second pulse generating unit 600 generates the second pulse signal H by using the rising transition of the output signal In_D from the delaying unit 800.

In turn, the signal combining unit 700 outputs the pulse signal Pulse Out that has the high level between the transition of the first pulse signal F to the low level and the transition of the second pulse signal H to the low level. Here, the width of the pulse signal Pulse Out is determined by the delay time of the delaying unit 800.

The used delaying unit 800 has the constant delay regardless of process condition change or voltage variation as described above so that the output pulse signal Pulse Out can have the constant pulse width regardless of process condition change or voltage variation.

Accordingly, when an external circuit receives such an output pulse signal Pulse Out, reliability of the operation of the circuit that receives the output pulse signal Pulse Out may be improved.

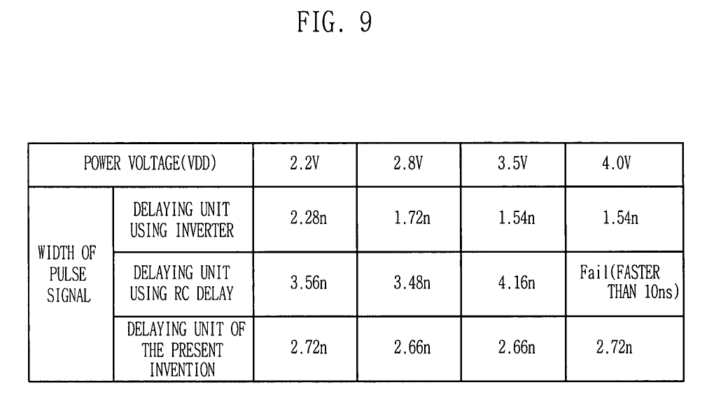

FIG. 9 offers a chart for comparing pulse width of the output of the pulse generating circuit in FIG. 5 to pulse width of the output of the pulse generating circuit in prior art when the power level of the power voltage varies.

Referring to FIG. 9, it can be seen that the pulse generating circuit that employs the conventional delay device using only the inverters or the RC delay shows significant variation of the pulse width of the output pulse signal of the pulse generating circuit when the power voltage VDD is changed.

On the contrary, the pulse generating circuit of the present invention shows rare variation for the pulse width of the output pulse signal even when the power voltage is changed.

As described above, according to the present invention, the pulse generating circuit generates the pulse signal having the constant pulse width and the constant delay regardless of the process condition and the power voltage variation.

Therefore, in the semiconductor integrated circuit using the pulse generating circuit of the present invention, erroneous operation can be reduced even when the power voltage or the process condition varies.

The present application contains subject matter related to Korean patent applications No. 2003-76839, filed in the Korean Patent Office on Oct. 31, 2003, the entire contents of which being incorporated herein by reference.

While the present invention has been described with respect to the particular embodiments, it will be apparent to those skilled in the art that various changes and modification may be made without departing from the spirit and scope of the invention as defined in the following claims.

1-26. (canceled)

27. A delay circuit for delaying a signal that is inputted to an input stage by a predetermined time to output to an output stage, comprising:
a first MOS transistor having one end coupled to a power voltage for transferring the power voltage to a signal transfer node in response to the signal that is inputted to an input stage;
a first delay device coupled between the other end of the first MOS transistor and the signal transfer node and having a first resistor device and a second MOS transistor;
a third MOS transistor having one end coupled to a ground voltage for transferring the ground voltage to the signal transfer node in response to the signal that is inputted to an input stage;
a fourth MOS transistor having one end coupled to the power voltage for transferring the power voltage to the output stage in response to the signal that is inputted to an input stage;
a fifth MOS transistor having one end coupled to the ground voltage for transferring the ground voltage to the output stage in response to the signal that is inputted to an input stage; and
a second delay device coupled between the fifth MOS transistor and the output stage and having a second resistor device and a sixth MOS transistor,
wherein the first and second delay devices have the same delay amount regardless of process condition or operating voltage variation.

28. The delay circuit as recited in claim 27, wherein the second and sixth MOS transistors are incessantly maintained in turn-on state.

29. The delay circuit as recited in claim 28, further comprising:
a first inverter for inverting an input signal to transfer the inverted input signal to the input stage; and
a second inverter for inverting a signal on the output stage.

30. The delay circuit as recited in claim 28, further comprising:
a first capacitor coupled between the power voltage and the signal transfer node;
a second capacitor coupled between the ground voltage and the signal transfer node.

31. The delay circuit as recited in claim 30, further comprising:
a third capacitor coupled between the power voltage and the output stage;
a fourth capacitor coupled between the ground voltage and the output stage.

32-37. (canceled)

38. A pulse generating circuit, comprising:
a first pulse generating means for generating a first pulse signal by using transition of an input signal;
a delaying means for delaying the input signal by a predetermined time;
a second pulse generating means for generating a second pulse signal by using the transition of an output signal from the delaying means; and
a signal combining means for receiving the first pulse signal and the second pulse signal to generate an output pulse signal,
wherein the delaying means includes:
a first MOS transistor having one end coupled to a power voltage for transferring the power voltage to a signal transfer node in response to a signal that is inputted to an input stage;
a first delay device coupled between the other end of the first MOS transistor and the signal transfer node and having a first resistor device and a second MOS transistor coupled to the first resistor device in parallel;
a third MOS transistor having one end coupled to a ground voltage for transferring the ground voltage to the signal transfer node in response to the signal that is inputted to the input stage;
a fourth MOS transistor having one end coupled to the power voltage for transferring the power voltage to the output stage in response to the signal that is inputted to the signal transfer node;
a fifth MOS transistor having one end coupled to the ground voltage for transferring the ground voltage to the output stage in response to the signal that is inputted to the signal transfer node; and
a second delay device coupled between the fifth MOS transistor and the output stage and having a second resistor device and a sixth MOS transistor coupled to the second resistor device in parallel,
wherein the first and second delay devices have the same delay amount regardless of process condition or operating voltage variation.

39. The pulse generating circuit as recited in claim 38, wherein the second and sixth MOS transistors are incessantly maintained in turn-on state.

40. The pulse generating circuit as recited in claim 39, further comprising:
a first inverter for inverting the input signal to transfer the inverted input signal to the input stage; and
a second inverter for inverting a signal on the output stage.

41. The pulse generating circuit as recited in claim 39, wherein the first pulse generating means includes:
a first inverting unit for inverting the input signal; and
a first NAND gate for performing a NAND operation of the input signal and an output of the first inverting unit.

42. The pulse generating circuit as recited in claim 39, wherein the second pulse generating means includes:
a second inverting unit for inverting the output signal of the delaying means; and
a second NAND gate for performing a NAND operation of the output signal of the delaying means and an output signal of the second inverting unit.

43. The pulse generating circuit as recited in claim 39, wherein the signal combining means includes:
third and fourth NAND gates, the third NAND gate receiving the first pulse signal at one end and an output signal of the fourth NAND gate at the other end, the fourth NAND gate receiving the second pulse signal at one end and an output of the third NAND gate at the other end; and
a buffer for buffering and outputting the output of the third NAND gate.

44. The pulse generating circuit as recited in claim 39, further comprising:
a first capacitor coupled between the power voltage and the signal transfer node;
a second capacitor coupled between the ground voltage and the signal transfer node.

45. The pulse generating circuit as recited in claim 39, further comprising:
a third capacitor coupled between the power voltage and the output stage;
a fourth capacitor coupled between the ground voltage and the output stage.
